(19) United States
(12) Patent Application Publication
(10) Pub. No.: US 2012/0023970 A1
(43) Pub. Date: Feb. 2, 2012

(54) COOLING AND HEATING WATER SYSTEM USING THERMOELECTRIC MODULE AND METHOD FOR MANUFACTURING THE SAME

(75) Inventors: Sung Ho Lee, Gyeonggi-do (KR); Yong Suk Kim, Gyeonggi-do (KR); Young Soo Oh, Gyeonggi-do (KR); Tae Kon Koo, Seoul (KR); Sung Kwon Wi, Seoul (KR)

(73) Assignee: SAMSUNG ELECTRO-MECHANICS, CO., LTD.

(21) Appl. No.: 12/947,061

(22) Filed: Nov. 16, 2010

(30) Foreign Application Priority Data
Jul. 29, 2010 (KR) 10-2010-0073588

(51) Int. Cl. F25B 21/02; H05K 13/00

(52) U.S. Cl. 62/3.2; 29/592.1

(57) ABSTRACT

Disclosed herein are a cooling and heating water system using a thermoelectric module and a method of manufacturing the same. The cooling and heating water system using a thermoelectric module includes first and second substrates disposed to be spaced apart from each other, while facing each other; a cooling water line formed in the first substrate so as to flow cooling water therethrough; a heating water line formed in the second substrate so as to flow heating water therethrough; first and second insulating layers disposed on the inner side surfaces of the first and second substrates, respectively; and a thermoelectric device interposed between the first and second insulating layers, whereby it is possible to variously control a temperature of drinking water without generating noise by using the thermoelectric module in cooling the drinking water.

### CROSS REFERENCE(S) TO RELATED APPLICATIONS

This application claims the benefit under 35 U.S.C. Section [120, 119, 119(e)] of Korean Patent Application Serial No. 10-2010-0073588, entitled “Cooling And Heating Water System Using Thermoelectric Module And Method For Manufacturing The Same” filed on Jul. 29, 2010, which is hereby incorporated by reference in its entirety into this application.

### BACKGROUND OF THE INVENTION

1. Technical Field

The present invention relates to a cooling and heating water system using a thermoelectric module and a method for manufacturing the same, and more particularly, to a cooling and heating water system using a thermoelectric module, which includes substrates having cooling and heating water lines through which drinking water can flow and a thermoelectric device to enable drinking water to be rapidly cooled, and a method for manufacturing the same.

2. Description of the Related Art

A sudden increase in use of fossil energy causes global warming and energy exhaustion, such that more research into a thermoelectric module capable of efficiently using energy has been recently conducted.

Herein, the thermoelectric module may be used as a power generator using a Seebeck effect in which electromotive force is generated when both ends of the thermoelectric device are provided with the difference in temperature or a cooler using a Peltier effect in which one end of the thermoelectric device generates heat and the other end thereof absorbs heat when direct current is applied to the thermoelectric device.

The thermoelectric module may include upper and lower electrodes, and a thermoelectric device interposed between the upper and lower electrodes. Herein, a substrate is disposed on each upper surface of the upper and lower electrodes in order to support the thermoelectric module. At this time, the substrate mainly uses an alumina substrate having excellent electrical insulation.

However, the alumina substrate has low thermal conductivity, such that the thermoelectric performance and the heat transfer performance of the thermoelectric module are degraded.

### SUMMARY OF THE INVENTION

An object of the present invention is to provide a cooling and heating water system using a thermoelectric module that includes each of the insulating substrates including passages through which cooling water and heating water flow to improve thermal conductivity and thereby to enable drinking water to be rapidly cooled, and a method for manufacturing the same.

According to an exemplary embodiment of the present invention, there is provided a cooling and heating water system using a thermoelectric module, including: first and second substrates disposed to be spaced apart from each other, while facing each other; a cooling water line formed in the first substrate so as to flow cooling water therethrough; a heating water line formed in the second substrate so as to flow heating water therethrough; first and second insulating layers disposed on the inner side surfaces of the first and second substrates, respectively; and a thermoelectric device interposed between the first and second insulating layers.

The cooling and heating water system using a thermoelectric module may further include: water inlets formed at ends of the cooling water line and the heating water line to introduce water; and water outlets formed at ends of the cooling water line and the heating water line to discharge water to the outside of the cooling and heating water system.

The first and second substrates may be made of a metal.

When the first and second substrates being disposed to be spaced apart from each other, while facing each other, the cooling water line formed in the first substrate so as to flow cooling water therethrough, the heating water line formed in the second substrate so as to flow heating water therethrough, the first and second insulating layers disposed on the inner side surfaces of the first and second substrates, respectively, and the thermoelectric device interposed between the first and second insulating layers form a single group, the cooling and heating water system may be configured of a plurality of groups by disposing the group in plural

Thermal grease may be further disposed between the plurality of groups.

When the cooling and heating water system is configured of the plurality of groups, substrates contacting each other may flow water in the same state, of heating water or cooling water.

The first and second insulating layers may be coated with any one of insulating oxides of Al₂O₃, ZnO and NiO.

According to another exemplary embodiment of the present invention, there is provided a method for manufacturing a cooling and heating water system using a thermoelectric module, including: disposing a first insulating layer on an inner side of a first substrate including a cooling water line; disposing a thermoelectric device on an inner side of the first insulating layer; disposing a second insulating layer on a side surface of the thermoelectric device so as to be symmetrical to the first insulating layer based on the thermoelectric device; and disposing a second substrate including a heating water line on a side surface of the second insulating layer so as to be symmetrical to the first substrate.

The cooling water line and the heating water line may further have water inlets introducing water at ends thereof.

The cooling water line and the heating water line may further have water outlets discharging water at ends thereof.

The first and second substrates may be made of a metal.

The first and second insulating layers may be coated with any one of insulating oxides of Al₂O₃, ZnO and NiO.

### BRIEF DESCRIPTION OF THE DRAWINGS

FIG. 1 is an exploded perspective view showing an example of a cooling and heating water system according to the present invention;

FIG. 2 is a perspective view of the cooling and heating water system according to the present invention;

FIG. 3 is a cross-sectional view of the cooling and heating water system taken along line I-I′ of FIG. 2;

FIG. 4 is an exploded perspective view showing another example of the cooling and heating water system according to the present invention;

FIG. 5 is a perspective view of the cooling and heating water system of FIG. 4; and

FIG. 6 is a cross-sectional view of the cooling and heating water system taken along line II-II′ of FIG. 5.

### DESCRIPTION OF THE PREFERRED EMBODIMENTS

Hereinafter, exemplary embodiments of the present invention will be described in detail with reference to a cooling and heating water system using a thermoelectric module. The exemplary embodiments of the present invention to be described below are provided by way of example so that the idea of the present invention can be sufficiently transferred to those skilled in the art to which the present invention pertains. Therefore, the present invention may be modified in many different forms and it should not be limited to the embodiments set forth herein. In the drawings, the size and the thickness of the apparatus may be exaggerated for the convenience. Like reference numerals denote like elements throughout the specification.

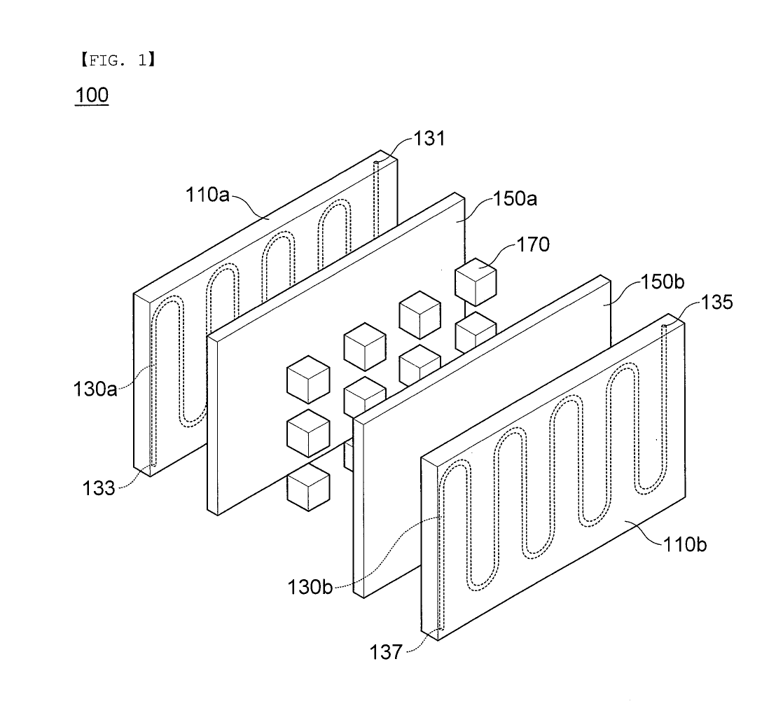

As shown, FIG. 1 is an exploded perspective view showing an example of a cooling and heating water system according to the present invention.

As shown in FIG. 1, a cooling and heating water system 100 includes first and second substrates 110a and 110b, first and second insulating layers 150a and 150b, and a thermoelectric device 170.

More specifically, the first and second substrates 110a and 110b may be disposed to be spaced apart from each other, while facing each other.

In this configuration, the first and second substrates 110a and 110b may be bonded to an external apparatus (not shown) to serve to absorb or dissipate heat from or to the outside through a heat exchange with the thermoelectric device 170.

That is, the first and second substrates 110a and 110b may serve to perform a heat transfer between the external apparatus and the thermoelectric device 170. Therefore, the efficiency of the thermoelectric module may be affected by thermal conductivity of the first and second substrates 110a and 110b.

Therefore, the first and second substrates 110a and 110b may be made of a metal having excellent thermal conductivity (for example, aluminum, copper, or the like). Thereby, thermal conductivity may be expected to be further improved.

In addition, the first substrate 110a includes a cooling water line 130a formed therein so as to flow cooling water therethrough.

The second substrate 110b includes a heating water line 130b formed therein so as to flow heating water therethrough. That is, the cooling water line 130a and the heating water line 130b mean a passage through which drinking water flows.

The cooling water line 130a and the heating water line 130b may be formed in the first substrate 110a and the second substrate 110b to have a curved shape as shown in FIG. 1. This may also be implemented to have another shape (for example, a straight line type, a diagonal line type, or the like) according to an operator's need.

Meanwhile, as shown in FIG. 1, the cooling water line 130a and the heating water line 130b may have water inlets 131 and 135 formed at ends thereof to introduce water.

In addition, the cooling water line 130a and the heating water line 130b may have water outlets 133 and 137 formed at ends thereof to discharge water to the outside of the cooling and heating water system.

The first and second insulating layers 150a and 150b may be disposed on the inner side surfaces of the first and second substrates 110a and 110b, respectively.

In this case, the first and second insulating layers 150a and 150b may be coated with any one of insulating oxides of Al₂O₃, ZnO and NiO.

In addition, the thermoelectric device 170 may be interposed between the first and second insulating layers 150a and 150b.

In this case, the thermoelectric device 170 may include a P-type semiconductor and an N-type semiconductor, which may be spaced apart from each other on the same plane by an optional interval to be alternately disposed.

As described above, the first substrate 110a and the second substrate 110b include the cooling water line and the heating water line, respectively. Therefore, a temperature of the second substrate 110b including the heating water line is relatively higher than a temperature of the first substrate 110a including the cooling water line, such that a heat dissipating rate can be accelerated. As a result, rapid cooling of the drinking water flowing through the cooling waterline can be performed due to the accelerated heat dissipating rate, such that efficiency of cooling/heating water supply can be maximized.

In addition, the first substrate 110a and the second substrate 110b are made of a metal material and the first and second insulating layers 150a and 150b are disposed therebetween to have high thermal conductivity, such that the rapid cooling efficiency of the drinking water can be expected to be further improved.

Meanwhile, the present invention has an advantage in that the heating water supply rate of the drinking water flowing through the heating water line can be increased due to the effects as described above.

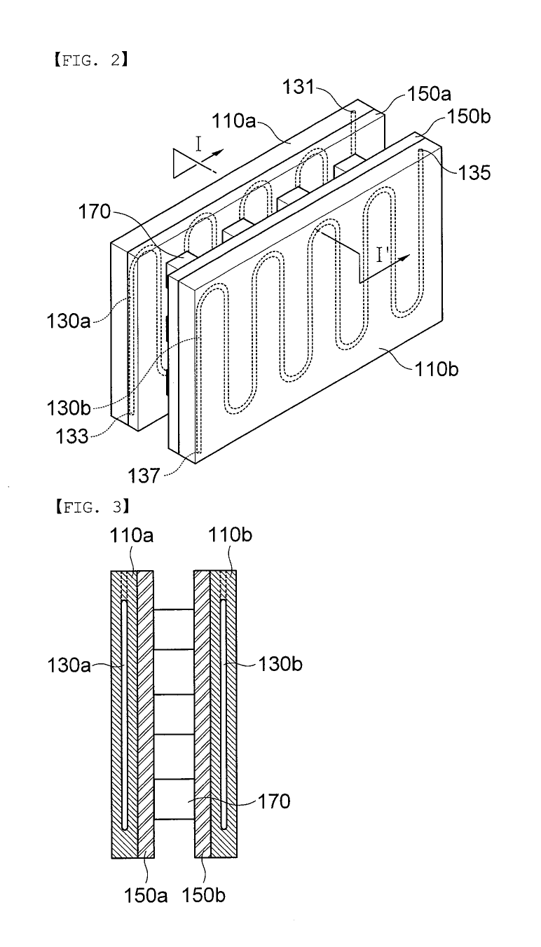

FIG. 2 shows a case in which each of the first and second substrates 110a and 110b, the first and second insulating layers 150a and 150b, and the thermoelectric device 170 shown in FIG. 1 is assembled.

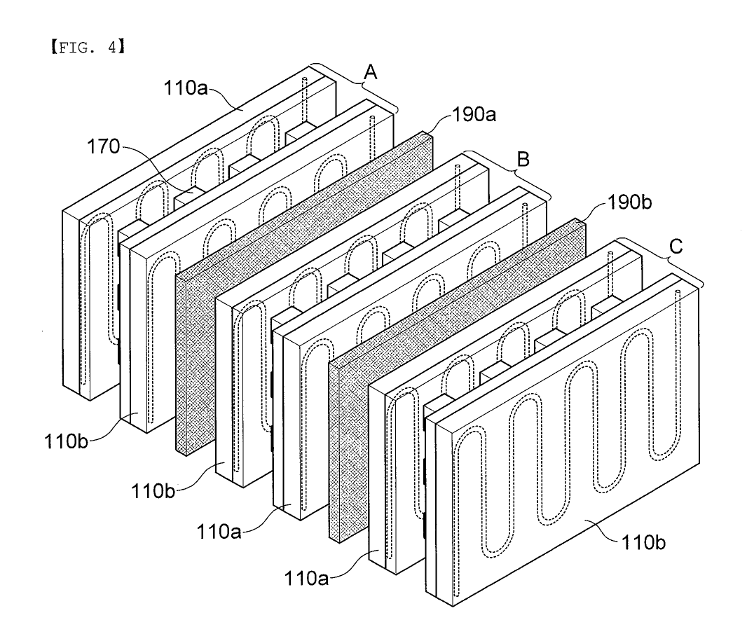

FIG. 3 is a cross-sectional view of the cooling and heating water system taken along line I-I′ of FIG. 2.

As shown in FIG. 3, in the cooling and heating water system 100, the cooling water line 130a through which drinking water flows is formed in the first substrate 110a and the first insulating layer 150a and the thermoelectric device 170 are disposed on the inner side surface of the first substrate 110a in sequence.

In addition, the second insulating layer 150b and the second substrate 110b including the heating water line 130b are disposed in sequence so as to be symmetrical to the first substrate 110a and the first insulating layer 150a based on the thermoelectric device 170.

Herein, the plurality of thermoelectric devices 170 may be disposed to be spaced apart from each other as shown in FIG. 3.

The cooling and heating water system shown in FIGS. 1 to 3 absorbs and dissipates heat of cooling and heating water from and to the substrate and the insulating layer at low power in a sleeping mode before being driven and rapidly supplies cooling and heating water when a supply signal of the cooling and heating water is generated from the outside.

Hereinafter, a case in which the first and second substrates 110a and 100b, the first and second insulating layers 150a and 150b, and the thermoelectric device 170 shown in FIGS. 1 to 3 are disposed in plural will be described by way of example.

This is a structure for facilitating the supply of cooling and heating water by connecting a plurality of thermoelectric modules when the cooling and heating water system using a single thermoelectric module is insufficient in consideration of the amount of the cooling and heating water.

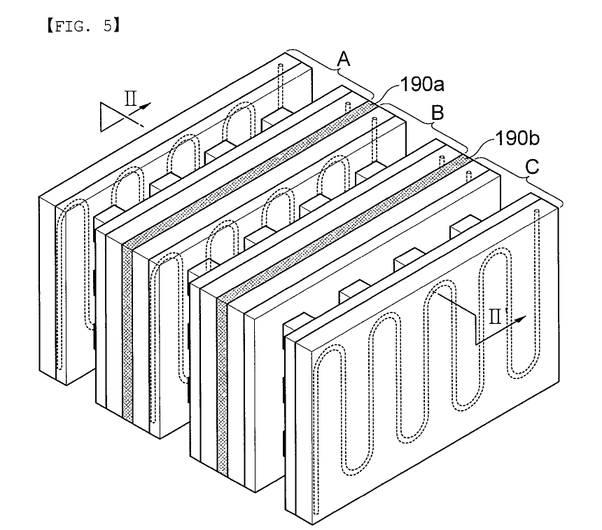

FIG. 4 is an exploded perspective view showing another example of the cooling and heating water system according to the present invention.

As shown in FIG. 4, when the first and second substrates 110a and 110b being disposed to be spaced apart from each other, while facing each other, the cooling water line 130a formed in the first substrate 110a so as to flow cooling water therethrough, the heating water line 130b formed in the second substrate 110b so as to flow heating water therethrough, the first and second insulating layers 150a and 150b disposed on the inner side surfaces of the first and second substrates 110a and 110b, respectively, and the thermoelectric device 170 interposed between the first and second insulating layers 150a and 150b form a single group (group A in FIG. 4), the cooling and heating water system 100 may be configured of a plurality of groups (group A, group B, and group C) by disposing the group in plural.

As shown in FIG. 4, thermal grease 190a and 190b may further be disposed between the plurality of groups (group A, group B, and group C).

Herein, the thermal grease may serve to fill the voids formed on each boundary surface and prevent thermal conductivity from being degraded due to the voids.

Meanwhile, when the cooing and heating water system 100 is configured of the plurality of groups, the substrates contacting each other flow water in the same state, of heating water or cooling water.

For example, a substrate including a cooling water line may be disposed to contact a substrate including a cooling water line, and a substrate including a heating water line may be disposed to contact a substrate including a heating water line.

This improves thermal transfer efficiency, thereby making it possible to shorten a time rendered in cooling water or heating water.

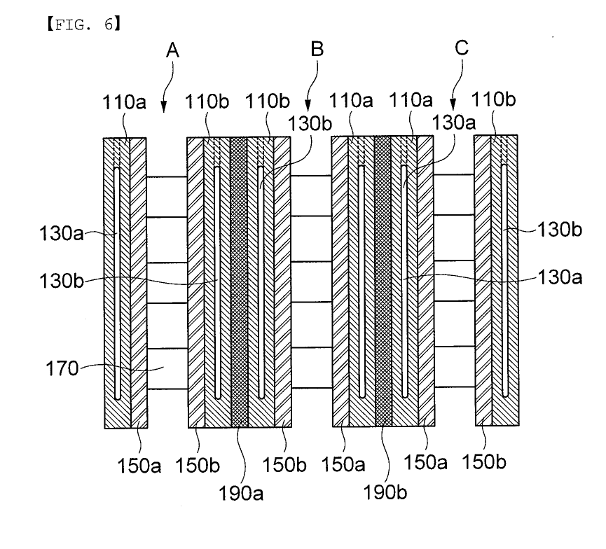

FIGS. 5 and 6 show a case in which each of group A, group B, and group C shown in FIG. 4 is assembled.

Although not shown, a method for manufacturing the cooling a heating water system according to the present invention will be described hereinafter.

First, the first insulating layer 150a may be disposed on the inner side of the first substrate 110a including the cooling water line 130a.

The thermoelectric device 170 may be disposed on the inner side of the first insulating layer 150a.

Then, the second insulating layer 150b may be disposed on the side surface of the thermoelectric device so as to be symmetrical to the first insulating layer 150a based on the thermoelectric device.

In addition, the second substrate 110b including the heating water line 130b may be disposed on the side surface of the second insulating layer 150b so as to be symmetrical to the first substrate 110a.

The cooling water line 130a and the heating water line 130b may further have the water inlets 131 and 135 introducing water at ends thereof.

In addition, the cooling water line 130a and the heating water line 130b may further have the water outlets 133 and 137 discharging water at ends thereof.

In addition, the first and second substrates 110a and 110b may be made of a metal.

The first and second insulating layers 150a and 150b may be coated with any one of insulating oxides of Al₂O₃, ZnO and NiO.

The cooling and heating water system using a thermoelectric module according to the present invention uses the thermoelectric module in cooling drinking water, thereby making it possible to variously control the temperature of the drinking water without generating noise.

In addition, the present invention uses the metal substrates and the passages formed in the metal substrates in the thermoelectric module, thereby making it possible to improve thermal conductivity as compared to the thermoelectric module according to the related art and thus to enable the drinking water to be rapidly cooled.

In addition, the present invention uses the thermoelectric module, such that no noise is generated when the cooling and heating water system operates.

Although the exemplary embodiments of the present invention have been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

What is claimed is:

1. A cooling and heating water system using a thermoelectric module, comprising:
first and second substrates disposed to be spaced apart from each other, while facing each other;
a cooling water line formed in the first substrate so as to flow cooling water therethrough;
a heating water line formed in the second substrate so as to flow heating water therethrough;
first and second insulating layers disposed on the inner side surfaces of the first and second substrates, respectively; and
a thermoelectric device interposed between the first and second insulating layers.

2. The cooling and heating water system using a thermoelectric module according to claim 1, further comprising:
water inlets formed at ends of the cooling water line and the heating water line to introduce water; and
water outlets formed at ends of the cooling water line and the heating water line to discharge water to the outside of the cooling and heating water system.

3. The cooling and heating water system using a thermoelectric module according to claim 2, wherein the first and second substrates are made of a metal.

4. The cooling and heating water system using a thermoelectric module according to claim 3, wherein when the first and second substrates being disposed to be spaced apart from each other, while facing each other, the cooling water line formed in the first substrate so as to flow cooling water therethrough, the heating water line formed in the second substrate so as to flow heating water therethrough, the first and second insulating layers disposed on the inner side surfaces of the first and second substrates, respectively, and the thermoelectric device interposed between the first and second insulating layers form a single group, the cooling and heating water system is configured of a plurality of groups by disposing the group in plural.

5. The cooling and heating water system using a thermoelectric module according to claim 4, wherein thermal grease is further disposed between the plurality of groups.

6. The cooling and heating water system using a thermoelectric module according to claim 5, wherein when the cooling and heating water system is configured of the plurality of groups, substrates contacting each other flow water in the same state, of heating water or cooling water.

7. The cooling and heating water system using a thermoelectric module according to claim 1, wherein the first and second insulating layers are coated with any one of insulating oxides of Al₂O₃, ZnO and NiO.

8. A method for manufacturing a cooling and heating water system using a thermoelectric module, comprising:
disposing a first insulating layer on an inner side of a first substrate including a cooling water line;
disposing a thermoelectric device on an inner side of the first insulating layer;
disposing a second insulating layer on a side surface of the thermoelectric device so as to be symmetrical to the first insulating layer based on the thermoelectric device; and
disposing a second substrate including a heating water line on a side surface of the second insulating layer so as to be symmetrical to the first substrate.

9. The method for manufacturing a cooling and heating water system using a thermoelectric module according to claim 8, wherein the cooling water line and the heating water line further have water inlets introducing water at ends thereof.

10. The method for manufacturing a cooling and heating water system using a thermoelectric module according to claim 9, wherein the cooling water line and the heating water line further have water outlets discharging water at ends thereof.

11. The method for manufacturing a cooling and heating water system using a thermoelectric module according to claim 10, wherein the first and second substrates are made of a metal.

12. The method for manufacturing a cooling and heating water system using a thermoelectric module according to claim 11, wherein the first and second insulating layers are coated with any one of insulating oxides of Al₂O₃, ZnO and NiO.
